(19) United States
(12) Patent Application Publication
(10) Pub. No.: US 2003/0030070 A1
(43) Pub. Date: Feb. 13, 2003

(54) Bipolar transistor

(76) Inventor: Fumihiko Hirose, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 10/103,743

(22) Filed: Mar. 25, 2002

(30) Foreign Application Priority Data
Mar. 28, 2001 (JP) 2001-093984

(51) Int. Cl. H01L 31/0328

(52) U.S. Cl. 257/197

(57) ABSTRACT

A bipolar transistor comprises an A layer of a first conductive type stacked on a semiconductor substrate of a first conductive type, a B layer of the first conductive type stacked on the A layer, the dopant concentrations of the B layer and the A layer differing, a C layer of a second conductive type stacked on the B layer, the conductive type of the C layer differing from that of the A layer, B layer and the substrate and, a D layer of the first conductive type stacked on the C layer, a collector electrode using the A layer, the B layer, and the substrate as a collector, a base electrode using the C layer as a base, and an emitter electrode using the D layer as an emitter.

### CROSS-REFERENCE TO RELATED APPLICATIONS

This application is based upon and claims the benefit of priority from the prior Japanese Patent Application No. 2001-093984, filed Mar. 28, 2001, the entire contents of which are incorporated herein by reference.

### BACKGROUND OF THE INVENTION

1. Field of the Invention

The present invention relates to a bipolar transistor for high power switching, and more particularly, to a switch device of a power supply circuit of electronics.

2. Description of the Related Art

Bipolar transistors are used as switching devices in power supply circuits of personal computers, air conditioners and electric vehicles. A bipolar transistor is a semiconductor device comprising an emitter, a base and a collector. More specifically, the bipolar transistor is formed of a semiconductor of a first conductive type, a semiconductor of a second conductive type and another semiconductor of the first conductive type in contact with each other. When a bipolar transistor is used as a switching element for switching a high voltage and a high current, the structure of the bipolar transistor becomes more complicated.

An example of a conventional bipolar transistor for a high-power switch will be explained with reference to FIG. 1. FIG. 1 shows an npn⁻n⁺ type Si transistor, in which a lightly-doped n (n⁻) type semiconductor layer 3, a p-type semiconductor layer 4, and an n-type semiconductor layer 5 are stacked on a semiconductor substrate 2 heavily doped with an n-type (n⁺) dopant. The n⁺ type substrate 2 and n⁻ type layer 3 serve as a collector, the p-type layer 4 as a base, and the uppermost n-type layer 5 as an emitter. Parts of the emitter 5 are removed to expose the surface of the base 4. Metal electrodes 6 and 7 are arranged in the exposed surfaces of the base 4 and emitter 5, respectively. The metal electrode 6 is directly attached in contact with the exposed surface of the base 4, serving as a base electrode. The metal electrode 7 is attached in contact with the exposed surface of the emitter 5, serving as an emitter electrode. Another metal electrode 8 is formed at the backside surface of the substrate 2, serving as a collector electrode.

FIG. 2 is a profile of dopant concentration of a bipolar transistor, showing the dopant concentration of the region below an emitter electrode. In the figure, the depth (μm) from a boundary between an emitter electrode and an emitter layer is plotted on the horizontal axis and a dopant concentration (cm⁻³) of each semiconductor layer is plotted on the vertical axis. In this example, the dopant concentration of the emitter 5 is set at 10¹⁹/cm³ or more and the dopant concentration of the base 4 is set within the range of 10¹⁷ to 10¹⁸/cm³. Note that the thickness (width) of the base 4 is set at 1.0 μm or less. This is because the excessively thick of the base 4 degrade, the switching speed and current gain. In usual, the dopant concentration of the n⁻ conductive type semiconductor of the collector 3 is set at 10¹⁵/cm³ or less. The thickness of the collector 3 must be sufficiently high so long as the breakdown voltage is in the required level.

Such a bipolar transistor is integrated into a switching circuit 10 shown in FIG. 3. The emitter 3 and collector 5 of the bipolar transistor 9 are connected by way of electrodes 7, 8, a load 12, and a voltage source 11. In this circuit 10, when a base current (Ib) is supplied from a base terminal 16 to an emitter terminal 17, a collector current (Ic) flowing from the collector 3 to the emitter 5 varies depending upon the magnitude of the base current (Ib). Making use of such a change in collector current, turn-on and off of the circuit is made.

When no base current flows (Ib=0) in a general bipolar transistor, the impedance between the emitter 5 and the collector 3 becomes high. As a result, no collector current (Ic=0) flows. Assuming that the region between the emitter 5 and the base 4 is regarded as a switch, the circuit is equivalent to be in a turn-off state since no collector current (Ic=0) flows. In contrast, when a predetermined current is supplied to the base 4, the impedance between the emitter 5 and the collector 3 becomes low. As a result, a current flows between the emitter 5 and collector 3. The circuit is equivalent to be in a turn-on state.

In the bipolar transistor for the aforementioned usage, the current gain and breakdown voltage are desirably as high as possible. The current gain used herein is defined as the ratio (Ic/Ib) of a collector current (Ic) to a base current (Ib) when the bipolar transistor is turned on. The higher the current gain (Ic/Ib) results in the smaller power consumption of a circuit for driving a transistor. The higher current gain is favorable in view of power saving.

On the other hand, the higher the breakdown voltage of the bipolar transistor allows the wide application filed of this transistor. As a result, a bipolar transistor can be used more in various fields. Thus, it is desirable that a bipolar transistor should have not only a high current gain but also a high breakdown voltage. However, the current gain and the breakdown voltage are not compatible (trade-off) in a conventional transistor. To describe more specifically, if the current amplification increases, the breakdown voltage decreases. Conversely, if the breakdown voltage increases, the current amplification decreases.

A bipolar transistor has an n⁻ layer in the collector portion to preserve a breakdown voltage. Since depletion occurs in the n⁻ layer by turning off the switch, a power supply voltage is applied to the n⁻ layer. The electric filed of the n⁻ layer is determined by the dopant concentration, the thickness of the n⁻ layer and the power source voltage. In an Si-based bipolar transistor, the dopant concentration of the n⁻ layer is generally set at as low as 10¹⁵/cm³ or less. In such a low dopant concentration, a breakdown voltage is determined by the thickness of the n⁻ layer.

In this case, the breakdown voltage V_{cbo} of the bipolar transistor is given by a product of the thickness L of the n⁻ layer and a coefficient k (V_{cbo}=kE₀L), where E₀ is the avalanche electric field of the n⁻ layer, the coefficient k is a constant falling within the range of 0.5 to 0.8, which is determined depending upon the structure of a bipolar transistor.

On the other hand, the current gain and the thickness L of the n⁻ layer negatively correlated. To explain more specifically, when a bipolar transistor is turned on, a current flows from the collector 3 to the emitter 5. However, electrons flow from the emitter 5 into the n⁻ type layer of the collector 3 through the base 4. At this time, holes flow from the base 4 into the n⁻ type layer to neutralize the n-layer. The distribution of carrier concentration within the transistor is shown in FIG. 4.

Such a phenomenon remarkably takes place when a circuit is operated at a low voltage while supplying a high current. This is called the “base-spreading effect” or “Kirk effect”. When the Kirk effect is taking place, most of a base current is due to a recombination current generated in the n⁻ layer.

As the thickness L of the n⁻ type layer increases, the recombination region increases, with the result that the recombination current increases, whereas the current gain decreases. In other words, as the thickness L of the n⁻ layer increases, the breakdown voltage increases whereas the current gain decreases. In contrast, as the thickness L of the n⁻ layer decreases, the breakdown voltage decreases whereas the current gain increases.

As described above, the high breakdown voltage and the high current gain are incompatible (trade-off) in a conventional bipolar transistor. It has been difficult to increase both characteristics up to a satisfactory level.

Problems associated with a bipolar transistor of an npn⁻n⁺structure have been explained. However, the same problems reside in a bipolar transistor of a reverse conductive type, a pnp⁻p⁺ structure.

### BRIEF SUMMARY OF THE INVENTION

An object of the present invention is to provide a bipolar transistor attaining a high current gain by suppressing the Kirk effect, while ensuring a high breakdown voltage.

A bipolar transistor according to the present invention comprises:

an A layer of a first conductive type provided on a semiconductor substrate of a first conductive type;

a B layer of the first conductive type provided on the A layer, the dopant concentrations of the B layer and the A layer differing;

a C layer of a second conductive type provided on the B layer, the conductive type of the C layer differing from that of the A layer, B layer and the substrate and;

a D layer of the first conductive type provided on the C layer;

a collector electrode using the A layer, the B layer, and the substrate as a collector;

a base electrode using the C layer as a base; and

an emitter electrode using the D layer as an emitter.

The terms “first conductive type” and “second conductive type” represent either an n-type or a p-type of the semiconductor. More specifically, provided that the n-type is regarded as a “first conductive type”, the p-type is a “second conductive type”. Conversely, provided that the p-type is regarded as a “first conductive type”, the n-type is a “second conductive type”.

It is preferable that the dopant concentration of the A layer is greater than that of the B layer by at the most 100 times. This is because the hole injection from a base is limited within the B layer, thereby preventing the holes from entering the A layer when a circuit is operated at a low voltage while supplying a high current. If the dopant concentration of the A layer exceeds 100 times that of the B layer, the increase of the breakdown voltage is decreases. As a result, substantial effects cannot be obtained.

Assuming that the thickness of the B layer is L_{B}, the mobility of carriers within the B layer is μ, the time for carrier recombination within the B layer is τ, and the voltage between the emitter and collector during the ON operation is V_{ON}, it is desirable that the thickness L_{B} of the B layer and the recombination time τ be set so as to satisfy the following equation (1).

$$τ > 1000 \frac{{L}_{B}^{2}}{μ {V}_{ON}} \qquad ( 1 )$$

The operational fundamental and various characteristics of the bipolar transistor of the present invention will be explained with reference to FIG. 5. In this case, an npn⁻ⁿⁿ⁺structure will be explained by way of example. However, the present invention is effective if a bipolar semiconductor of a reverse conductive type, that is, a pnp⁻pp⁺ structure, is used.

The transistor of the present invention is formed by stacking an n-type layer (A type) 3a, an n⁻ type layer (B layer) 3b, and a p-type layer (C layer) 4, and an n-type layer 5 on an n-type substrate 2.

The difference between the transistor of the present invention and a conventional transistor will be described. The collector of a conventional transistor has two-layered structure, an n⁺ type substrate and an n⁻ layer 3, as shown in FIG. 1. In contrast, the collector 3A of the transistor of the preset invention has three-layered structure of an n⁺ type substrate 2, a layer 3a, and an n⁻ layer 3b as shown in FIGS. 5 and 6.

In the transistor of the present invention, depletion occurs simultaneously in both the A layer and the B layer when a switch is turned off, with the result that the electric field is applied to both the A layer and B layer. Assuming that a portion to which the breakdown voltage is applied has a length (thickness), Lrev, Lrev is almost equal to the sum of thicknesses of the A layer and the B layer, as expressed by the following equation (2).

Lrev=Thickness(A)+Thickness(B) (2)

On the other hand, when a circuit is operated at a low voltage while supplying a high current, the Kirk effect occurs. As a result, holes flow into the lightly doped B layer to neutralize is region. However, holes do not flow into the A layer since the A layer is heavily doped. Therefore, a recombination current, which damages the current gain, is generated only within the B layer. Provided that the thickness (length) of the region in which recombination current is generated is designated as the length of a recombination region, Lrec, the following relationship (3) is established.

Lrec=Thickness(B) (3)

In the transistor of the present invention, there is a relationship,

Lrev=Lrec+thickness (A),

where the thickness (A) represents the thickness of the A layer.

Whereas, in a conventional transistor the relationship, there is a relationship

Lrec=Lrec.

From the above, in the transistor of the present invention, the breakdown voltage is improved by the thickness of the A layer. Since the breakdown voltage is improved by the presence of the A layer, the thickness of the B layer can be reduced by the thickness of the A layer. As a result, the current gain can be increased. By virtue of this, the bipolar transistor of the present invention successfully overcomes the trade-off between the breakdown voltage and the current gain, and thus attains to have not only a high breakdown voltage but also high current amplification.

In this invention, the dopant concentration of each of the layers is defined. The reasons will be explained.

The dopant concentration of the A layer is set to be larger than that of the B layer. This is because holes entering from the base are held within the B layer and thereby prevented from entering into the A layer. To efficiently prevent holes from entering into the A layer, it is necessary to set the dopant concentration of the A layer to be larger than the concentration of electrons (holes in the case of pnp⁻pp⁺) injected from the emitter and present in the A layer.

When the dopant concentration of the A layer excessively increases, depletion rarely occurs within the A layer when a transistor is turned off. As a result, the breakdown voltage cannot be improved.

The present inventors have repeated a computer simulation. As a result, they found that if the dopant concentration of the A layer exceeds 100 times that of the B layer, the breakdown voltage is not improved so much. The effect of the present invention cannot be obtained.

In the present invention, the recombination time τ of carriers in the B layer is defined. This is to prevent the current gain from dropping due to the Kirk effect. This is one of the objects of the present invention. When the bipolar transistor having the structure according to the present invention is operated at a low voltage while supplying a high current, holes are injected from the base to the B layer. When electrons are injected from the emitter to the B layer and the A layer through the base, and cause recombination in the B layer, a base current increases.

On the other hand, if carriers cause recombination in the A layer and the underlying substrate, a collector current generates. Therefore, the recombination of carriers within the B layer must be prevented and electrons injected from the emitter must be sent to the A layer and thereunder. This can be achieved if the moving time, T_{B}, of carriers within the B layer is quite smaller than the recombination time τ. The electric field applied to the B layer is approximated by V_{ON}/L_{B}. If the carrier mobility is expressed by μ, the following relationships (4) to (6) are established.

$$\begin{matrix}{T}_{B} = \frac{{L}_{B}}{( μ \cdot \frac{{V}_{ON}}{{L}_{B}} )} = \frac{{L}_{B}^{2}}{μ {V}_{ON}} & ( 4 ) \\ τ >> {T}_{B} & ( 5 ) \\ τ >> \frac{{L}_{B}^{2}}{μ {V}_{ON}} & ( 6 )\end{matrix}$$

Under these conditions, the recombination of carriers within the B layer can be suppressed, attaining high current gain. The present inventors have conducted various studies on how extent of the is moving time T_{B} of carriers is set to be longer than the recombination time τ in practice. As a result, they found that if the recombination time τ is longer by about 1000 times than the moving time T_{B}, the decrease of current amplification can be negligibly small.

To avoid the decrease of current gain, it is desirable that the recombination time τ of carriers within the B layer be set to be sufficiently longer than the moving time T_{B}. More specifically, the recombination time τ is preferably set to be not smaller than 1000 times the moving time T_{B}. Conversely to say, the moving time T_{B} of carriers within the B layer is set to be not greater than 1/1000 of the recombination time τ.

The recombination time τ can be controlled by the crystallinity, the doping level and the defect density where the recombination takes place. More specifically, the recombination time τ can be increased by improving the crystallinity of the B layer. Therefore, the B layer of a transistor may be formed while preventing the crystallinity deterioration and suppressing the amount of a dopant, so as to satisfy the aforementioned equation (6).

The bipolar transistor of the present invention is formed by a chemical vapor deposition. The chemical vapor deposition used herein is a method of depositing a semiconductor film on the surface of a substrate, which is carried by filling a container with a raw material gas and placing a heated substrate in the container. The chemical vapor deposition methods include an atmospheric CVD method, a low-pressure CVD method, a plasma CVD method. The CVD method is performed by using an apparatus shown in FIG. 7.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a schematic cross-sectional view showing a conventional high power bipolar transistor;

FIG. 2 is a profile of the dopant concentration of the layers below the emitter electrode of a conventional bipolar transistor;

FIG. 3 is a circuit diagram having a bipolar transistor integrated therein;

FIG. 4 is a profile of the carrier density of the layers below the emitter electrode when a conventional bipolar transistor is turned on (ON operation);

FIG. 5 is a schematic cross-sectional view of a bipolar transistor for explaining the function and effects of the present invention;

FIG. 6 is a schematic cross-sectional view of a bipolar transistor according to an embodiment of the present invention;

FIG. 7 is a schematic block diagram showing an apparatus for use in manufacturing a bipolar transistor;

FIG. 8 is a depth profile of the carrier concentration of a bipolar transistor according to the present invention when it is operated under a low voltage while supplying a high current; and

FIG. 9 is a depth profile of the field intensity when a bipolar transistor according to an embodiment of the present invention is turned off.

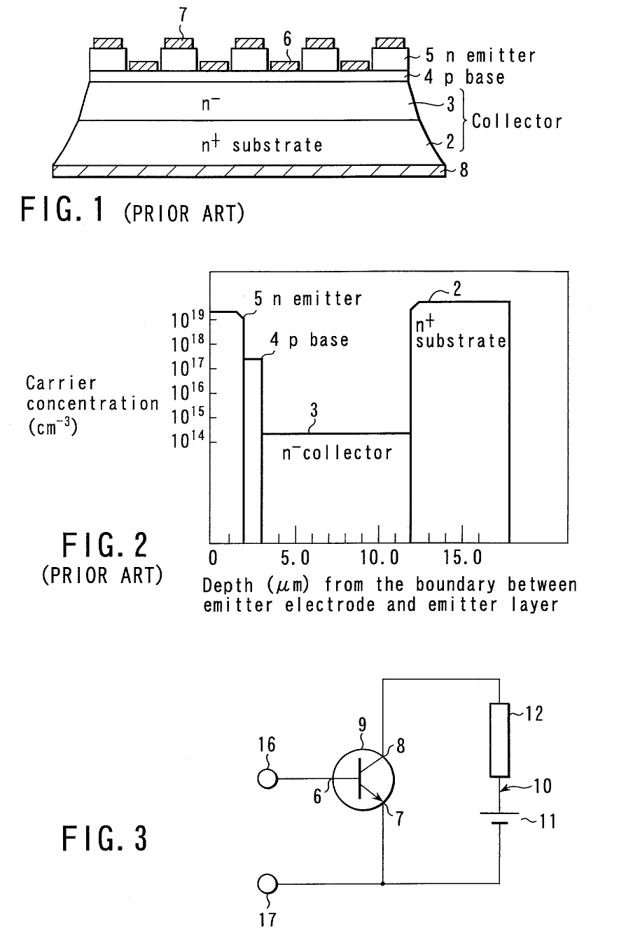

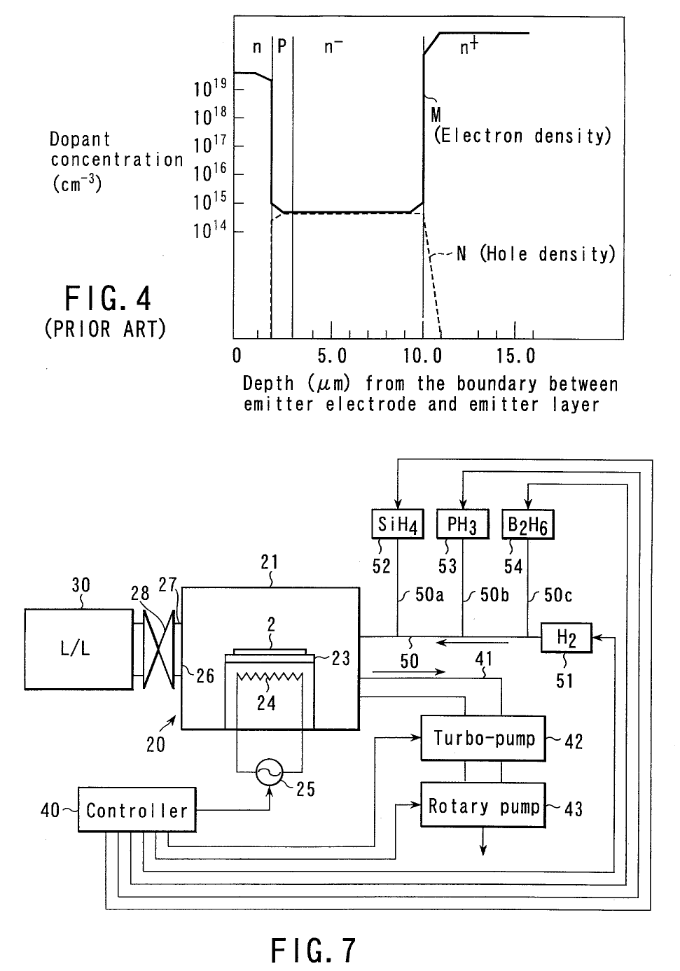

### DETAILED DESCRIPTION OF THE INVENTION

Preferred embodiments according to the present invention will be explained with reference to the accompanying drawings.

### Embodiments

The bipolar transistor shown in FIG. 6 has an npn⁻nn⁺ structure, which is formed by stacking an n-type semiconductor layer (A layer) 3a, an n⁻-type semiconductor layer (B layer) 3b, a p-type semiconductor layer (C layer) 4, and an n-type semiconductor layer (D layer) 5 on an n⁺ type substrate 2 in this order. The bipolar transistor is used as a high-power switching element. A collector 3A is formed of three layers, namely, the n⁺-type substrate 2, the n-type layer 3a, and the n⁻ layer 3b. To function the collector 3A of the three-layered structure, a collector electrode 8 is formed by coating the back surface of the substrate 2 with a metal such as aluminum. Furthermore, to function the C layer 4 as a base, parts of the D layer 5 are removed to expose the surface of the C layer 4 and a base electrode 6 of a metal such as aluminum is attached to the exposed surface of the C layer 4. Furthermore, to function the D layer 5 as an emitter, an emitter electrode 7 of a metal such as aluminum is attached on the remaining D layer 5.

The bipolar transistor is formed by using a reduced-pressure CVD apparatus shown in FIG. 7.

The chamber 21 and loadlock chamber 30 of the reduced pressure CVD apparatus 20 are communicably connected by way of a substrate transfer passage 27. Both chamber 21 and loadlock chamber 30 communicate through a gate valve 28. The silicon wafer 2 to be used as a transistor substrate is loaded into and unloaded from the chamber 21 of the CVD apparatus by way of a loadlock chamber 30 by a transfer mechanism (not shown). An opening portion 26 of the substrate transfer passage 27 is formed at one of two side surfaces of the chamber 21.

An exhaust duct 41 is formed at the other side of the chamber 21. A turbo molecular pump 42 and a rotary pump 43 are provided as part of the exhaust duct 41 to evacuate the chamber 21. The turbo molecular pump 42 is arranged upstream (close to the chamber 21) of the rotary pump 43. The chamber 21 is roughly evacuated by the rotary pump 43 and completely evacuated by the turbo pump 42.

The chamber 21 houses a stage 23, on which a substrate 2 is mounted. The stage 23 houses a heater 24 for heating the substrate 2.

Four gas supply sources 51, 52, 53 and 54 communicate with the chamber 21 through pipes 50, 50a, 50b, and 50c respectively. The first gas supply source 51 supplies hydrogen gas (H₂) to the chamber 21 through the main pipe 50. Hydrogen gas (H₂) is used for diluting a film-forming gas and doping gas. The second gas supply source 52 supplies silane gas (SiH₄) or disilane gas (Si₂H₆) to the chamber 21 through the branched pipe 50a and the main pipe 50. The third gas supply source 53 supplies phosphine gas (PH₃) to the chamber 21 by way of a branched pipe 50c and the main pipe 50. The fourth gas supply source 54 supplied diborane gas (B₂H₆) to the chamber 21 through the branched pipe 50c and the main pipe 50.

Each of the gas supply sources 51, 52, 53 and 54 has a pressure control valve and a mass flow controller (not shown) installed therein. Since the flow rates of four types of gases are accurately controlled by the pressure control valves and the mass flow controllers, they are merged in the main pipe 50 at a predetermined ratio and introduced into the chamber 21.

The operations of a power source 25 for the heater and power sources of the gate valve 28, the turbo molecular pump 42 and the rotary pump 43 are separately controlled by a controller 40.

### EXAMPLE 1

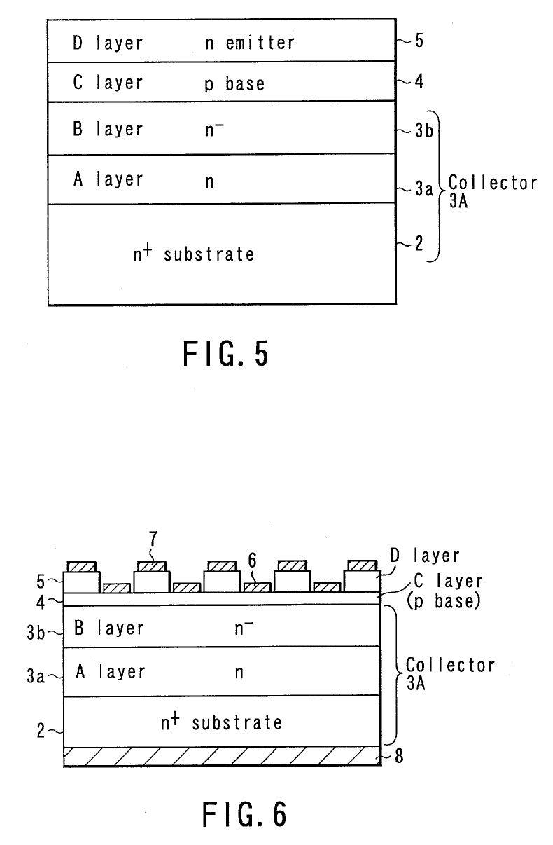

Now, a transistor according to Example 1 will be explained with reference to FIGS. 5 and 6 and Tables 1 and 2.

The surface of a silicon substrate 2 was cleaned by an RCA method to remove oxygen and carbon from the surface to obtain the silicon substrate 2 having a specific film resistance of about 0.001 Ω/cm (Step S1). The substrate 2 was an n⁺ type silicon wafer. The dopant(P) concentration was about 8×10¹⁹/cm³. The RCA method is a wet chemical cleaning method using a plurality of chemical solutions described in W. Kern and D. A. Puotinen RCA Rev. Vol. 31 (1970) 187.

After the cleaning step, the Si substrate 2 was transferred to the CVD apparatus 20 and mounted on the stage 23. Subsequently, the gate valve 28 was shut and the chamber 21 was evacuated by pumps 42 and 43 until the inner pressure reached 1×10⁻⁹ Torr. The substrate 2 was heated by a heater 24 up to 800 to 900° C.

While the substrate 2 was being heated, gases were supplied to the chamber 21 separately from three gas supply sources 51, 52 and 53. The A layer was formed by using a gas mixture of raw material gases, namely, disilane (Si₂H₆), silane (SiH₄), and phosphine (PH₃). The gas mixture was diluted by supplying hydrogen gas at a predetermined flow rate, thereby preparing the mixture at a predetermined dilution rate. The P dopant concentration of the n-type Si film 3a (A layer) was determined by a mixed ratio of phosphine to disilane or silane. To obtain a P dopant concentration of about 1×10¹⁵/cm³, a partial-pressure ratio of pH₃/Si₂H₆ (SiH₄) was set at about 0.10 ppm. In this manner, the A layer doped with phosphorus (P) at a concentration of about 1×10¹⁵/cm was formed up to a thickness of 10 μm on the surface of the n⁺ type Si substrate 2 (Step S2).

Subsequently or after the chamber 21 is evacuated, gases were supplied to the chamber 21 from three gas supply sources 51, 52 and 53 at predetermined flow rates. To form the B layer, a gas mixture of raw material gases, namely, disilane (Si₂H₆) or silane (SiH₄) and phosphine (PH₃) were used. The gas mixture was diluted with hydrogen gas supplied at a predetermined flow rate to obtain the mixture at a predetermined dilution rate.

The P dopant concentration of the n⁻ type Si film 3b (B layer) was determined by a mixing ratio of phosphine to disilane or silane. To obtain a P dopant concentration of about 1×10¹⁴/cm³, a partial-pressure ratio of pH₃/Si₂H₆ (SiH₄) was set at about 0.01 ppm. In this manner, the B layer 3b doped with phosphorus (P) at a concentration of about 1×10¹⁴/cm was formed up to a thickness of 10 μm on the A layer 3a (Step S2).

After the chamber 21 was evacuated, gases were supplied to the chamber 21 from three gas sources 51, 52 and 54 at predetermined flow rates while heating the substrate 2. To form the C layer, a gas mixture of raw material gases, namely, disilane (Si₂H₆) or silane (SiH₄) and phosphine (PH₃) was used. The gas mixture was diluted with hydrogen gas supplied at a predetermined flow rate to obtain the mixture at a predetermined dilution rate.

The B dopant concentration of the p-type Si film 4 (C layer) was determined by a mixing ratio of phosphine to disilane or silane. To obtain a B dopant concentration of about 2×10¹⁷/cm³, a partial pressure ratio of B₂H₆/Si₂H₆ (SiH₄) was set at about 20 ppm and a substrate temperature during film-formation time was set at, for example, 650° C. or more. In this manner, the p-type C layer doped with boron(B) at a concentration of about 2×10¹⁷/cm³ was formed up to a thickness of 0.4 μm on the n-type Si film 3 (Step S4).

After the chamber 21 was evaluated, gases were supplied to the chamber 21 from three gas sources 51, 52 and 54 at predetermined flow rates while heating the substrate 2. To form the D layer, a gas mixture of raw material gases, namely, disilane (Si₂H₆) or silane (SiH₄) and phosphine (PH₃) were used. The gas mixture was diluted with hydrogen gas supplied at a predetermined flow rate to obtain the mixture at a predetermined dilution rate.

The P dopant concentration of the n-type Si film 5 (D layer) was determined by a mixing ratio of phosphine to disilane or silane. To obtain a P dopant concentration of about 1×10²⁰/cm³, a partial pressure ratio of pH₃/Si₂H₆ (SiH₄) was set at about 1.00 ppm. In this manner, the D layer doped with phosphorus(P) at a concentration of about 1×10²⁰/cm³ was formed up to a thickness of 1.0 μm on the C type layer (Step S5).

The heating of the substrate 2 with a heater was terminated and simultaneously the chamber 21 was evacuated. Subsequently, the gate valve 28 was opened to unload the stacked substrate 2 from the chamber 21. The surface of the stacked substrate 2 was masked and the D layer 5 was etched by using a pattern by a wet-etching method or a dry-etching method. In this way, a plurality of element-isolation grooves was formed at predetermined intervals (Step S6). The C layer 4 was exposed at the bottom of the groove.

The base electrode 6 was formed by depositing aluminum on the exposed surface of the C layer 4 (Step S7). In addition, aluminum was deposited on the remaining surface of the D layer 5 to form an emitter electrode 7 (Step S8).

Furthermore, a collector electrode 8 was formed by depositing aluminum on the backside surface of the substrate 2 (step S9). The stacked substrate thus obtained was cleaved at the grooves into chips by a dice machine. The surfaces of the chips were covered with a protecting film except electrodes 6, 7 and 8 to obtain bipolar transistors as a final product (Step S10).

FIG. 6 shows a schematic cross-sectional view of the transistor thus obtained. The chip area of the bipolar transistor of Example 1 was set at 0.16 cm². The area of the emitter 5 was set at 0.1 cm² and the area of the base 4 was set at 0.06 cm².

The conductive type, dopant concentration, thickness, carrier lifetime with respect to the layers A to D are listed in Table 1. More specifically, the substrate 2, the A layer 3a, and the B layer 3b are doped at concentrations of 8×10¹⁹/cm³, 1×10¹⁵/cm³, 1×10¹⁴/cm³, respectively. The A layer and the B layer have the same thickness of 10 μm.

TABLE 1
Characteristics of portions of transistor according to Example

| | | | | | Carrier | Electron |
|---|---|---|---|---|---|---|
| | | Conductive | | Dope | life | mobility |
| Portion | Function | type | Thickness (μm) | concentration | (μs) | (cm²/Vs) |
| D | Emitter | n | 1.0 | 1 × 10²⁰/cm³ | 0.1 | 150 |
| C | Base | p | 0.4 | 2 × 10¹⁷/cm³ | 0.1 | 400 |
| B | Collector | n⁻ | 10 | 1 × 10¹⁴/cm³ | 10 | 1100 |
| A | Collector | n | 10 | 1 × 10¹⁵/cm³ | 10 | 1100 |
| Substrate | Collector | n⁺ | 550 | 8 × 10¹⁹/cm³ | 0.1 | 150 |

A maximum current of a transistor designed in Example 1 was set at 12 A. Based on the aforementioned data, the characteristics of the transistor are estimated by calculation. The characteristics were estimated on the assumption that a predetermined potential was given to each electrode as a boundary condition. A base current (Ib) and a collector current (Ic) were obtained by solving the following equations (7) to (11) without contradiction.

Jₙ=qDₙgradn−qμₙngradφ (7)

Jₚ=qDₚgradp−qμₚpgradφ (8)

where Jₙ is an electron current density, Jₚ is a hole current density, q is an electron charge, n is an electron density, p is a hole density, φ is distribution of an electric potential, μₙ is an electron mobility, and μₚ is a hole mobility.

The following equations (9) and (10) are given as equations for current continuation.

$$\begin{matrix}\frac{ⅆ n}{ⅆ t} = - \frac{1}{q} div {J}_{n} + Gn - Un & ( 9 ) \\ \frac{ⅆ p}{ⅆ t} = - \frac{1}{q} div {J}_{p} + Gp - Up & ( 10 )\end{matrix}$$

where Gn and Gp are an electron-generating rate and a hole-generating rate per unit time, respectively. Un and Up are recombination rates of electrons and holes per unit time. The following equation (11) is given as the Poisson equation.

∇²φ=−q(Nd−Na+p−n) (11)

where Nd is the concentration of n-type dopant atoms and Na is the concentration of p-type dopant atoms.

A collector current (Ic) and base current (Ib) were respectively obtained by solving the following equations (7) to (11). The current gain were evaluated based on Ic and Ib. As a result, a current gain 110 was obtained as shown in Table 2.

The breakdown voltage was evaluated by solving the following equations (7) to (11) assuming that a predetermined voltage was applied between the base and the collector. With an increase of applied voltage up to a certain level, the field intensity inside a transistor increases. When a field intensity of 300 kV/cm² is obtained which causes the avalanche breakdown, the voltage between the base and the collector is regarded as a breakdown voltage of the transistor. As a result, a breakdown voltage of 375V was obtained as shown in Table 2.

TABLE 2
Estimated Values of transistor according to Example

| Item | Example |
|---|---|
| Current amplification | 110 |
| Voltage between collector | |
| and emitter 1.0 V; | |
| Collector current 12 A | |
| Breakdown voltage (V) | 375 |

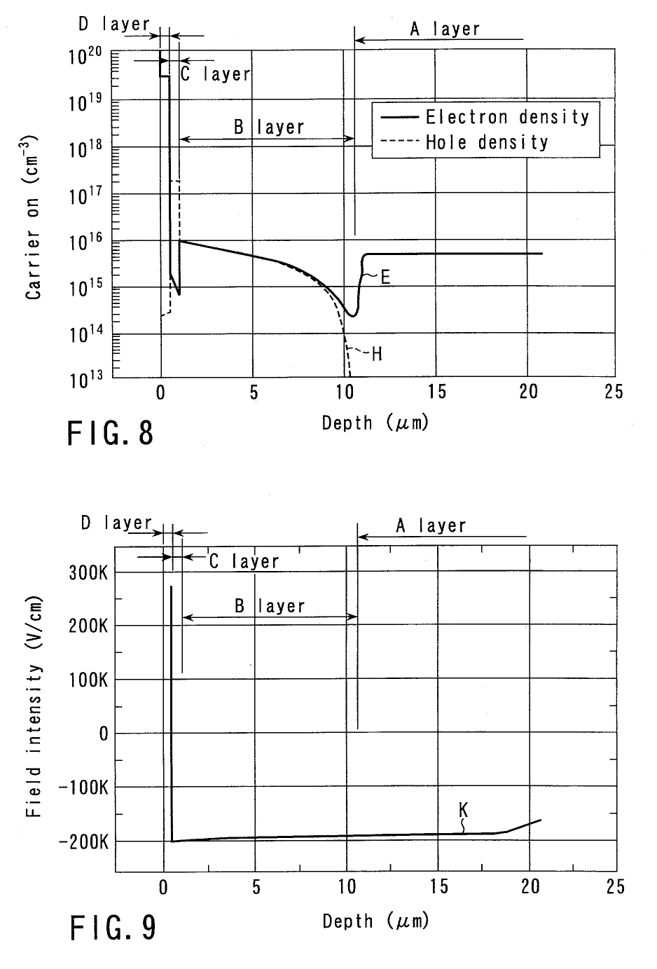

FIG. 8 shows a depth profile of carrier concentration when the bipolar transistor of this example is operated at a low voltage while supplying a high current. In FIG. 8, the depth (μm) from the surface of the transistor is plotted on the horizontal axis and the carrier concentration per unit volume (particles/cm³) is plotted on the vertical axis. The voltage between the collector and the emitter is set at 1.0V and the collector current is set at 12 A. Solid line E exhibits the distribution of the electron density. Broken line H exhibits the distribution of the hole density. As is apparent from the figure, the C layer and B layer have a high hole density distribution, whereas the A layer has a low hole density distribution. From the profile of the hole density, it is found that holes are injected from the base layer, C layer, to B layer but not injected to the A layer. This fact demonstrates that the Kirk effect is observed only in the B layer and is not in the A layer.

FIG. 9 shows a depth profile of the electric field distribution of a transistor when the base current is turned off and a voltage of 300 V is applied between the emitter and the collector. In the figure, the depth (μm) from the boundary between the emitter and the base is plotted on the horizontal axis and the field intensity (V/cm) is plotted on the vertical axis. Line K shows the distribution of the electric field of each layer. As is apparent from the figure, the electric field is generated from the A layer to the B layer. This is because depletion occurs in the A layer and the B layer, with the result that the voltage between the emitter and collector is mostly applied to the A layer and B layer. From the above, it is found that the Kirk effect of the transistor designed in this embodiment is stopped within the B layer, and that breakdown voltage is generated in both the A layer and the B layer.

### Control 1

Now, Control 1 will be explained. As a control experiment, a bipolar transistor without the A layer was designed. The characteristics of the transistor of Control 1 are shown in Table 3.

TABLE 3
Characteristics of portions of transistor according to Control Experiment

| | | | | | Carrier | Electron |
|---|---|---|---|---|---|---|
| | | Conductive | | Dope | life | mobility |
| Portion | Function | type | Thickness (μm) | concentration | (μs) | (cm²/Vs) |
| D | Emitter | n | 1.0 | 1 × 10²⁰/cm³ | 0.1 | 150 |
| C | Base | p | 0.4 | 2 × 10¹⁷/cm³ | 0.1 | 400 |
| B | Collector | n | 10 | 1 × 10¹⁴/cm³ | 10 | 1100 |
| A | Omitted | Omitted | Omitted | Omitted | Omitted | |
| Substrate | Collector | n | 550 | 8 × 10¹⁹/cm³ | 0.1 | 150 |

The breakdown voltage and current amplification of the transistor are calculated by computer simulation. The results are shown in Table 4.

TABLE 4
Estimated Values of transistors according
to Example and Control

| Item | Example | Control |
|---|---|---|
| Current amplification | 110 | 110 |
| Voltage between | | |
| collector and emitter | | |
| 1.0 V; | | |
| Collector current | | |
| 12 A | | |
| Breakdown voltage (V) | 375 | 275 |

Control 1 and Example 1 are listed in Table 4. The breakdown voltage of the transistor of Example 1 is higher by 100V than that of the transistor of Control 1. It is therefore demonstrated that the breakdown voltage can be improved in the transistor of the present invention.

As a result of the calculation performed by the present inventors, to obtain the same breakdown voltage as that in Example 1 by the transistor of Control 1, it turns out that the thickness of the B layer 3b must be changed from 10 μm to 16 μm. However, if the thickness is increased, the current amplification becomes 45. From the above, the present invention made it possible to mitigate the trade-off between the current amplification and the breakdown voltage.

### Control 2

In Control 2, the B layer of a transistor was formed so as to have a carrier lifetime τ outside the range defined by the equation (1). The. transistor of Control 2 was substantially the same as that of Control 1 except the B layer.

When the carrier life of the B layer was calculated by the equation (6), the right side (L_{B}²/μVₒₙ) becomes 1×10⁻⁹s. Assuming that the carrier life of the A layer was set at 1×10⁻⁶s (1 μs), which was 1000 times larger than the carrier life of the B layer, the current amplification falls by about 10% than the case of 1×10⁻⁶s (10 μs). Practically this raises no problem. If the carrier life was not greater than 1×10⁻⁶s (1 μs), the current amplification was significantly low. For instance, in the case of the carrier life was 1×10⁻⁷s (0.1 μs), the current amplification decreased to about ⅓ of the case of 1×10⁻⁶s (10 μs). Furthermore, in the case of 1×10⁻⁸s (0.01 μs), the carrier life decreased to about 1/10 compared to the case of the 1×10⁻⁶s (10 μs). As described above, any one of the transistors according to Control 2 had a problem in practical use.

### Control 3

In Control 3, the dopant concentration of the A layer was set at 100 times as larger as that of the B layer. The transistor of Control 3 was substantially the same as the A layer of the transistor of Example 1 except the A layer.

The current gain and the breakdown voltage of Control 3 were the same as those of a conventional transistor having no A layer. It was demonstrated that it was important to regulate the dopant concentration of the A layer within a proper range in order to obtain the effect of the present invention.

The bipolar transistor of the present invention enables to provide almost the same high breakdown voltage equivalent to that of a conventional product and provide a current gain higher than that of a conventional one. The bipolar transistor of the present invention is extremely useful as a switching element of a power circuits for personal computers, air conditioners, or electric cars.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A bipolar transistor comprising
an A layer of a first conductive type provided on a semiconductor substrate of a first conductive type;
a B layer of the first conductive type provided on the A layer, the dopant concentrations of the B layer and the A layer differing;
a C layer of a second conductive type provided on the B layer, the conductive type of said C layer differing from that of the A layer, B layer and the substrate and;
a D layer of the first conductive type provided on the C layer;
a collector electrode using the A layer, the B layer, and the substrate as a collector;
a base electrode using the C layer as a base; and
an emitter electrode using the D layer as an emitter.

2. A bipolar transistor according to claim 1, wherein said dopant concentration of the A layer is greater than that of the B layer by at the most 100 times.

3. A bipolar transistor according to claim 1, wherein a recombination time z and a thickness L_{B} are set so as to satisfy the following equation:
τ>1000L_{B}²/μV_{ON} (1)
where L_{B} is the thickness of the B layer, μ is the carrier mobility in the B layer, τ is the recombination time of carriers in the B layer, and Vₒₙ is the voltage between the emitter and collector while a circuit is closed.

4. A bipolar transistor according to claim 3, wherein the moving time, T_{B}, of carriers is sufficiently smaller than the recombination time of carriers in the B layer.

5. A bipolar transistor according to claim 4, wherein the moving time, T_{B}, is 1/1000 or less the recombination time, τ.
